(19) United States
(12) Patent Application Publication
(10) Pub. No.: US 2007/0012421 A1
(43) Pub. Date: Jan. 18, 2007

(54) GREASE PROTECTING APPARATUS FOR HEAT SINK

(76) Inventors: Yeu-Lih Lin, Shenzhen (CN); Chin-Lung Chen, Shenzhen (CN); Jian-Qing Sheng, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/306,250

(22) Filed: Dec. 21, 2005

(30) Foreign Application Priority Data
Jul. 15, 2005 (TW) 094212075

(51) Int. Cl. H05K 7/20

(52) U.S. Cl. 165/80.2; 165/185; 361/705

(57) ABSTRACT

A grease protecting apparatus (10) includes a heat sink (12), and a grease cover (14). The heat sink includes a bottom surface (122) for contacting with a heat-generating component. A layer of thermal grease (16) is spread on the bottom surface of the heat sink. The grease cover is attached to the bottom surface of the heat sink and covers the grease to protect the grease from contamination. The cover includes a main body (142) defining a protecting space (143) therein for covering the grease, and two wings (144) extending from two opposite sides of the main body for attaching the grease cover to the bottom surface of the heat sink. The wings defines a plurality of perforations (148) therein to make the wings be capable of tilted upwardly and downwardly.

### FIELD OF THE INVENTION

The present invention relates generally to a grease protecting apparatus, and particularly to a grease protecting cover to separate thermal grease spread on a heat dissipating apparatus from surrounding articles.

### DESCRIPTION OF RELATED ART

A layer of thermal grease is usually spread on a bottom surface of a heat sink to improve heat conductivity between the heat sink and an electronic heat-generating component. The heat generated by the electronic component causes the thermal grease to become liquid, enabling the thermal grease to fill in air gaps formed between the heat sink and the electronic component, thereby improving heat conductivity between the heat sink and the electronic component.

Since the thermal grease is not solid at ambient temperature, it may contaminate surrounding articles or be contaminated by dust or foreign particles before the heat sink is assembled to the electronic component. To avoid the contamination, a grease protecting cover is needed to separate the thermal grease from the surrounding articles.

A grease protecting cover made of plastics is conventionally used for separating the thermal grease from the surrounding articles. The grease cover includes a main body, a protecting space formed at a middle portion of the main body for separating the thermal grease from the surrounding articles, and two wings horizontally extending from two opposite sides of the main body. A layer of adhesive is affixed to each of the wings of the cover, to attach the cover onto the heat sink. In order to firmly attach the cover onto the heat sink, the wings are preferably inherently oriented at a horizontal direction. However, since the cover is made of plastics, the wings are possible to deform under internal stress, for example, thermal stress resided in the cover due to a heat pressing for forming the cover. This deformation may cause the wings not to be horizontally oriented, thereby making the wings have a tendency to separate from the bottom surface of the heat sink after the wings are adhered to the heat sink. When the force for the deformation induced by the internal stress is larger than the adhering force, the wings and accordingly the cover are separated from the heat sink, whereby the grease can no longer be protected by the cover. To solve this problem, it is necessary to devise a grease cover, which has a reduced internal stress affecting the wings for attaching the cover to the heat sink, whereby a reliable attachment of the wings and accordingly the cover to the bottom surface of the heat sink can be ensured.

### SUMMARY OF INVENTION

The present invention relates to a grease protecting apparatus. According to a preferred embodiment of the present invention, the grease protecting apparatus includes a heat sink, and a grease cover. The heat sink includes a bottom surface for contacting with a heat-generating component. A layer of thermal grease is spread on the bottom surface of the heat sink. The grease cover is attached to the bottom surface of the heat sink and covers the grease to protect the grease from contamination. The cover includes a main body defining a protecting space therein for covering the grease, and two wings extending from two opposite sides of the main body. Two sheets of adhesive are applied on the wings, respectively. The adhesive is used to attach the wings and accordingly the grease cover to the bottom surface of the heat sink. The wings define a plurality of perforations in connecting portions between the main body and the wings, for increasing flexibility of the connecting portions of the grease cover, thereby reducing internal stress caused by forming the cover in affecting the wings. Thus, a tendency of deformation of the wings after they are bonded to the bottom surface of the heat sink is lessened. Accordingly, the grease cover is firmly attached to the bottom surface of the heat sink.

Other advantages and novel features of the present invention will become more apparent from the following detailed description of preferred embodiment when taken in conjunction with the accompanying drawings, in which:

### BRIEF DESCRIPTION OF DRAWINGS

FIG. 1 is an exploded, isometric view of a grease protecting apparatus according to a preferred embodiment of the present invention;

FIG. 2 is an assembled view of the grease protecting apparatus of FIG. 1;

FIG. 3 is an isometric view of a grease cover of the grease protecting apparatus of FIG. 1, viewed from a different aspect;

FIG. 4 is an isometric view of the grease cover of FIG. 3, as one of the wings of the grease cover is turned upwardly; and

FIG. 5 is an isometric view of a grease cover of a grease protecting apparatus according to another embodiment of the present invention.

### DETAILED DESCRIPTION

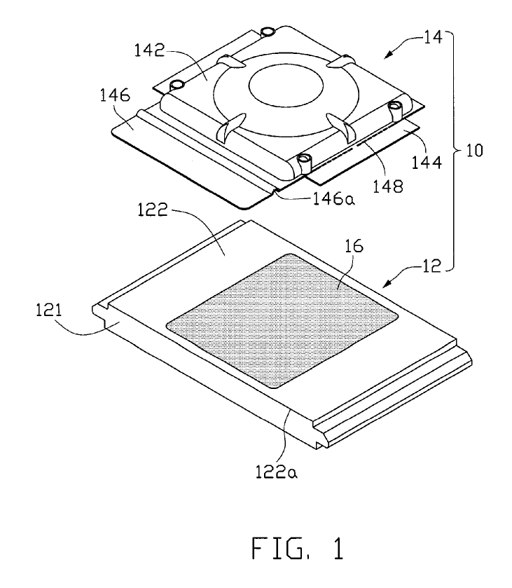

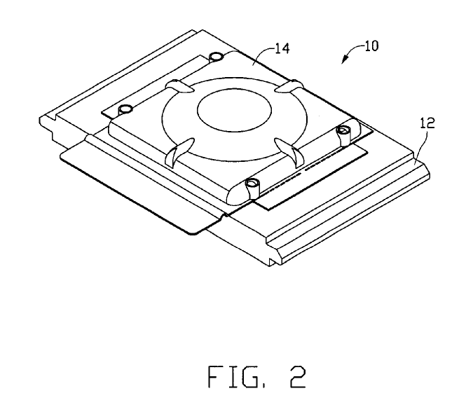

Referring to FIGS. 1 and 2, a grease protecting apparatus 10 according to a preferred embodiment of the present invention includes a heat sink 12, and a grease cover 14. A layer of thermal grease 16 is spread on a middle portion of a bottom surface 122 of a base 121 of the heat sink 12, for improving heat conductivity between the heat sink 12 and an electronic heat-generating component (not shown) to which the heat sink 12 is to be mounted for absorbing heat therefrom. The cover 14 is attached to the bottom surface 122 of the base 121 of the heat sink 12, for enclosing the thermal grease 16, thereby preventing the thermal grease 16 from contaminating surrounding articles or being contaminated by dust or foreign articles.

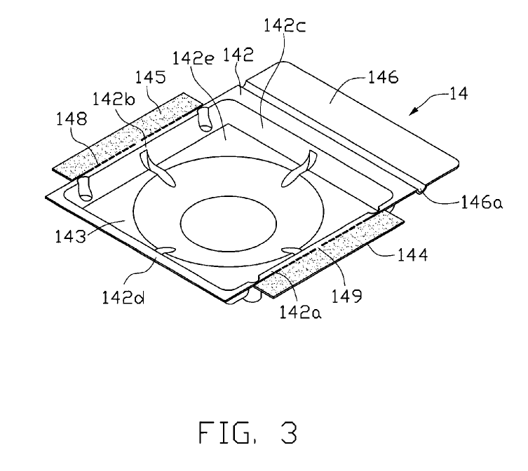

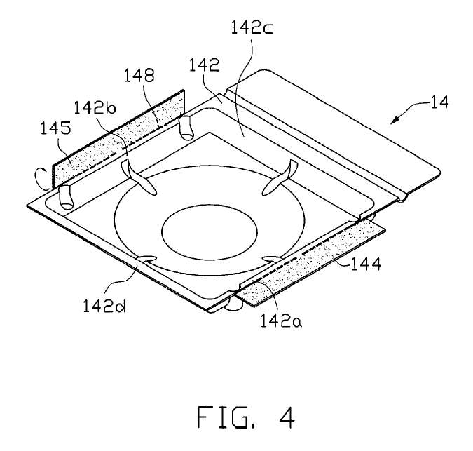

Particularly referring to FIGS. 3 and 4, the grease cover 14 is made of plastics materials, and includes a rectangular main body 142 with four sidewalls 142a, 142b, 142c, and 142d disposed around four sides of a top cover 142e of the main body 142, respectively, two wings 144 horizontally extending from the two opposite sidewalls 142a, 142b of the main body 142, and a flange 146 horizontally extending from the sidewall 142c of the main body 142. The grease cover 14 defines a line of perforations 148 at a connecting portion 149 between the main body 142 and each of the wings 144. Two sheets of adhesive 145 are applied on the wings 144 of the cover 14, to adhesively attach the cover 14 onto the bottom surface 122 of the base 121 of the heat sink 12. It is well known by those skilled in the art that the perforations 148 can be replaced by recesses which do not extend through the cover 14. The provision of the perforations 148 or the recesses is for weakening a connection between the wings 144 and the main body 142, thereby lessening an internal stress in affecting the wings 144. The internal stress, for example, a thermal stress, is resided in the grease cover 14, particularly, in the main body 142 due to the manufacturing of the grease cover 14 by a heat process, for example, heat pressing. The internal stress may cause the wings 144 to deform after they are adhered to the bottom surface 122 of the heat sink 12, which in turn, makes the wings 144 and the grease cover 14 to separate from the heat sink 12.

The main body 142 forms a protecting space 143 enclosed by the four sidewalls 142a, 142b, 142c, 142d below the top cover 142e of the main body 142. The protecting space 143 is above the bottom surfaces of the wings 144 for accommodating the thermal grease 16, whereby the grease cover 14 separates the thermal grease 16 from surrounding environment.

The flange 146 is located outside a side 122a of the heat sink 12 as the grease cover 14 is mounted on the heat sink 12. So a user can easily grasp the flange 146 to exert a force to the cover 14 to pull the cover 14 away from the heat sink 12. After the cover 14 is removed, the thermal grease 16 is exposed and the heat sink 12 is ready to be mounted to the electronic heat-generating component. A ripple 146a is formed on the flange 146 at a position thereof adjacent to the sidewall 142c of the main body 142. The ripple 146a makes the flange 146 be capable of being tilted upwardly, away from the bottom surface 122 of heat sink 12, so that the user can easily grasp the flange 146.

The perforations 148 are distributed along longitudinal directions of the wings 144, respectively. The perforations 148 decrease areas of the connecting portions 149 between the main body 142 and the wings 144, to increase the flexibility of the connecting portions 149, thereby making the wings 144 be capable of tilted upwardly and downwardly easily.

In assembly of the grease protecting apparatus 10, protecting films (not shown) covered on the adhesive 145 are removed. The sidewall 142d of the grease cover 14 is positioned on the bottom surface 122 of the heat sink 12 adjacent to the thermal grease 16 and distant from the side 122a of the heat sink 12. Then, the grease cover 14 rotates around the sidewall 142d of the main body 142 toward the bottom surface 122 of the heat sink 12, until the adhesive 145 applied on the wings 144 contact with the bottom surface 122 of the base 121 of the heat sink 12. The wings 144 are pressed downwardly to make the bottom surfaces of the wings 144 intimately affixed to the bottom surface 122 of the heat sink 12, thereby firmly attaching the grease cover 14 to the bottom surface 122 of the base 121 of the heat sink 12. In this position, the thermal grease 16 is accommodated in the protecting space 143 of the grease cover 14 and separated from the surroundings.

In disassembly of the grease protecting apparatus 10, a pulling force is exerted on the flange 146 of the grease cover 14, for making the wings 144 of the grease cover 14 rotating around the sidewall 142d of the main body 142 and away from the bottom surface 122 of the base 121 of the heat sink 12, to take the grease cover 14 off the base 121 of the heat sink 12.

In the present invention, the perforations 148 decrease the areas of the connecting portions 149 between the main body 142 and the wings 144, which increases the flexibility of the connecting portions 149. So the wings 144 can be pressed toward the bottom surface 122 of the heat sink 12 easily and reliably secured at that affixed position, thereby preventing the grease cover 14 from falling off the bottom surface 122 of the heat sink 12 due to the deformation of the wings 144.

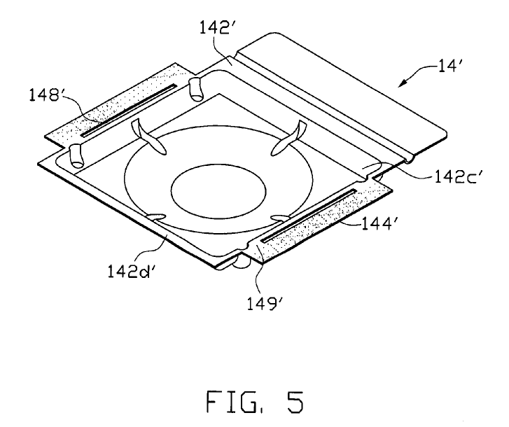

Referring to FIG. 5, a grease cover 14′ of a grease protecting apparatus according to a second embodiment of the present invention is shown. In this embodiment, the grease cover 14′ defines two slots 148′ at the connecting portions 149′ between the main body 142′ and the wings 144′ of the grease cover 14′, respectively. The slots 148′ also decrease areas of the connecting portions 149′ of the grease cover 14′, thereby increasing the flexibility of the connecting portions 149′, making the wings 144′ be easily pressed toward the bottom surface of the heat sink without rebound from the affixed position. In this embodiment, each wing 144′ connects with the main body 142′ of the cover 14′ at two ends thereof. Alternatively, the wing 144′ may be connected with the main body 142′ of the cover 14′ at one end. In detail, a first wing 144′ connects with the main body 142′ of the cover 14′ at an end adjacent to the sidewall 142d′ of the main body 142′, while a second wing 144′ connects with the main body 142′ of the cover 14′ at an end adjacent to the sidewall 142c′ of the main body 142′.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A grease protecting cover comprising:
a main body defining a protecting space therein, configured for accommodating thermal grease spread on a bottom surface of a heat sink therein; and
two wings extending from two opposite sides of the main body, configured for being applied with two sheets of adhesive thereon to attach the grease cover to the bottom surface of the heat sink; and
a plurality of voids defined in connecting portions between the main body and the wings, for increasing flexibility of the connecting portions of the grease cover.

2. The grease protecting cover as described in claim 1, wherein the voids are perforations arranged in two lines in the connecting portions, respectively.

3. The grease protecting cover as described in claim 1, wherein the recesses are two slots extending along longitudinal directions of the wings, respectively.

4. The grease protecting cover as described in claim 3, wherein each of the wings includes one end connected with the main body of the grease cover.

5. The grease protecting cover as described in claim 4, wherein said one end of each of the wings is located adjacent to one of other two opposite sidewalls of the main body.

6. The grease protecting cover as described in claim 3, wherein each of the wings includes two ends connected with the main body of the grease cover.

7. The grease protecting cover as described in claim 1, wherein a flange extends from the main body between the two opposite sides.

8. The grease protecting cover as described in claim 7, wherein a ripple is formed on the flange to make the flange be capable of being tilted upwardly.

9. A grease protecting apparatus comprising:
a heat sink comprising a bottom surface configured for contacting with a heat-generating component;
a layer of thermal grease spread on the bottom surface of the heat sink;
a grease cover attached to the bottom surface of the heat sink and covering the grease to protect the grease from contamination, the cover comprising:
a main body defining a protecting space therein for covering the grease; and
two wings extending from two opposite sides of the main body for attaching the grease cover to the bottom surface of the heat sink, the wings defining a plurality of voids therein to facilitate the wings to be tilted upwardly and downwardly.

10. The grease protecting apparatus as described in claim 9, wherein the voids are perforations arranged in two lines in the two wings respectively.

11. The grease protecting apparatus as described in claim 9, wherein the voids are recesses arranged in two lines in the two wings respectively.

12. The grease protecting apparatus as described in claim 9, wherein the voids are two slots in the two wings, respectively, each of the two slots extending along a longitudinal direction of a corresponding wing.

13. The grease protecting apparatus as described in claim 12, wherein each of the wings includes one end connected with the main body of the grease cover.

14. The grease protecting apparatus as described in claim 12, wherein each of the wings includes two ends connected with the main body of the grease cover.

15. A heat sink assembly, comprising:
a heat sink having a bottom surface for contacting with a heat-generating electronic component;
thermal grease provided on the bottom surface of the heat sink; and
a grease cover attached to the bottom surface of the heat sink and covering the thermal grease, the grease cover comprising:
a main body defining a protecting space receiving the thermal grease therein;
at least a wing extending from the main body and attached to the bottom surface of the heat sink; and
a void defined in the wing near the main body to weaken a connection between the wing and the main body.

16. The heat sink assembly of claim 15, wherein the void includes a plurality of perforations.

17. The heat sink assembly of claim 15, wherein the void includes a plurality of recesses.

18. The heat sink assembly of claim 15, wherein the void includes a slot.

19. The heat sink assembly of claim 15, wherein the grease cover further comprises a flange extending from the main body to a position beyond a side of the heat sink for facilitating a user to grip to peel the grease cover away from the heat sink.

20. The heat sink assembly of claim 19, wherein the flange forms a ripple thereon.
